(19) United States
(12) Patent Application Publication
(10) Pub. No.: US 2019/0158127 A1
(43) Pub. Date: May 23, 2019

(54) ENCODING AND DECODING ARCHITECTURE FOR HIGH-SPEED DATA COMMUNICATION SYSTEM AND RELATED PHYSICAL LAYER CIRCUIT, TRANSMITTER AND RECEIVER AND COMMUNICATION SYSTEM THEREOF

(71) Applicant: M31 Technology Corporation, Hsinchu County (TW)

(72) Inventor: Yueh-Chuan Lu, New Taipei City (TW)

(21) Appl. No.: 15/956,709

(22) Filed: Apr. 18, 2018

Related U.S. Application Data
(60) Provisional application No. 62/590,352, filed on Nov. 23, 2017.

(51) Int. Cl. H03M 13/37; H03M 9/00; H03M 7/30

(52) U.S. Cl. CPC H03M 13/3769; H03M 7/3066; H03M 9/00

(57) ABSTRACT

The present invention proposes an inventive encoding and decoding architecture for use in a physical layer of a high-speed serial data communication system, such as, MIPI C-PHY. Embodiments of the present invention include encoding chains and decoding chains adaptable to physical layer circuits of transmitters and receivers, respectively. The physical layer circuit of a transmitter includes: an encoding chain and a parallel-to-serial (P2S) converter. The encoding chain having a plurality of encoding unit coupled in series, and is arranged to receive a plurality of first symbols and convert each of the symbols to a corresponding wire state, thereby to generate a plurality of wire states. The P2S converter is coupled to the encoding chain, arranged to receive the plurality of wire states and serialize the plurality of wire states to provide a sequence of wire states.

### CROSS REFERENCE TO RELATED APPLICATIONS

This application claims the benefit of U.S. Provisional Application No. 62/590,352, filed on Nov. 23, 2017. The entire contents of the related applications are incorporated herein by reference.

### BACKGROUND OF THE INVENTION

### 1. Field of the Invention

The present invention relates generally to high-speed data communications, and more particularly, to encoding and decoding architecture for high-speed serial data communication system and related method, physical layer circuit, transmitter and receiver and communication system thereof.

### 2. Description of the Prior Art

Mobile devices, such as smartphones, include a variety of components for different purposes, such as, application processors, displays, CMOS image sensors. These components need to be interconnected by physical interface. For example, the application processor may provide frame data to the display through an interface for presenting visual contents. Alternatively, the CMOS image sensors may provide sensed image data to the application processor through an interface for exporting photos or videos.

The Mobile Industry Processor Interface (MIDI) specifications, which are standardized by the MIPIalliance, are widely used for signal communications and data transfer between the above mentioned components in the mobile devices. MIPI C-PHY is one of the MIDI specifications, which is newly developed and defined in order to meet requirement of high-speed transmission and provide high throughput for specific data, such as, frame data or image data. MIPI C-PHY introduces 3-phase symbol encoding to transmit data symbols on 3-wire lanes, or trios, where each trio includes an embedded clock. These signals having three levels, do not use the standard NRZ format of signaling, and are single ended. At any given point in time, no signals are at the same voltage levels. The MIPI C-PHY effectively can achieve high-speed signal communications and can provide high throughput with a bit rate of at least 2.5 Gbps.

To reach such high data rate, delay of hardware components need to be very short in order to avoid timing violation. However, in order to optimize energy, supply voltage of a mobile device is usually configured to be as low as possible. Hence, due to the low voltage operation and huge gate count in modern hardware components, it is difficult to shorten delays (such as gate delays) of the hardware components (such as combination logic circuits) in a modern complicated serial communication system, such as a MIPI C-PHY communication system. As a result, timing violation may occur if the overall gate delays of hardware components fail to keep up with a timing requirement of a unit interval of the transmission.

### SUMMARY OF THE INVENTION

In view of the above-mentioned problem, it is one object of the present invention to provide an encoding architecture and a corresponding decoding architecture, thereby to avoid a potential timing violation in a high-speed serial data communication system, such as MIPI C-PHY. In the encoding architecture and decoding architecture of the present invention, encoding and decoding circuits are implemented with multiple encoding and decoding units coupled in series, respectively. In addition, a sequence of the encoding circuit and a serializer are inverted compared to encoding architecture in the conventional art, while a sequence of the decoding circuit and a deserializer are also inverted compared to decoding architecture in the conventional art.

According to one embodiment of the present invention, a physical layer circuit at a transmitter is provided. The physical layer circuit comprises: an encoding chain and a parallel-to-serial (P2S) converter. The encoding chain has a plurality of encoding unit coupled in series and is arranged to receive a plurality of first symbols and convert each of the symbols to a corresponding wire state, thereby to generate a plurality of wire states. The P2S converter is coupled to the encoding chain and arranged to receive the plurality of wire states and serialize the plurality of wire states to provide a sequence of wire states.

According to one embodiment of the present invention, a method for use in a physical layer circuit at a transmitter is provided. The method comprises: receiving a plurality of first symbols and converting a symbol value of each of the plurality of first symbols to a corresponding wire state, thereby to generate a plurality of wire states; and receiving the plurality of wire states and serializing the plurality of wire states to provide a sequence of wire states.

According to one embodiment of the present invention, a physical layer circuit at a receiver is provided. The physical layer circuit comprises: a serial-to-parallel (S2P) converter and a decoding chain. The S2P converter is coupled to a multi-wire communication link, and arranged receive a sequence of write states transmitted through the multi-wire communication link and deserialize the sequence of write states to provide a plurality of wire states. The decoding chain has a plurality of decoding unit coupled in series and is arranged to receive the plurality of wire states and convert each of the plurality of wire states to a corresponding symbol value, thereby to generate a plurality of first symbols.

According to one embodiment of the present invention, a method for use in a physical layer circuit at a receiver is provided. The method comprises: receiving a sequence of write states and deserializing the sequence of write states to provide a plurality of wire states; and receiving the plurality of wire states and converting each of the plurality of wire states to a corresponding symbol value of a symbol, thereby to generate a plurality of first symbols.

According to one embodiment of the present invention, a communication system based on a multi-wire communication link is provided. The communication system comprises: a transmitter and a receiver. The transmitter comprises: a controller, a first physical layer circuit and a first interfacing circuit. The controller is arranged to provide a word of data. The first physical layer circuit is coupled to the controller and arranged to generate a sequence of wire states according to the word of data. The first physical layer circuit comprises an encoding chain arranged to convert a plurality of first symbols that are not serialized into a plurality of wire states. The first interfacing circuit is coupled to the first physical layer circuit and the multi-wire communication link and, is arranged to controlling levels of a plurality of wires of the multi-wire communication link according to the sequence of wire states generated by the first physical layer circuit. The receiver comprises a second interfacing circuit, a second physical layer unit and a controller. The second interfacing circuit is coupled to the multi-wire communication link, arranged extract the sequence of wire states from the wires of the multi-wire communication link. The second physical layer unit is coupled to the second interfacing circuit, arranged to reproduce the word of data according the sequence of wire states. The second physical layer unit comprises: a decoding chain arranged to convert a plurality of wire states that are deserialized from the sequence of the wire states, into a plurality of first symbols. The controller is coupled to the second physical layer circuit and arranged to receive and process the word of data.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an overview of a communication system according to one embodiment of the present invention.

FIG. 2 illustrates a state diagram regarding wire states and possible transitions in MIPI C-PHY interface.

FIGS. 3A-3D illustrates how the encoding architecture of the present invention works according to one embodiment of the present invention.

FIGS. 4A-4D illustrates how the decoding architecture of the present invention works according to one embodiment of the present invention.

### DETAILED DESCRIPTION

In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

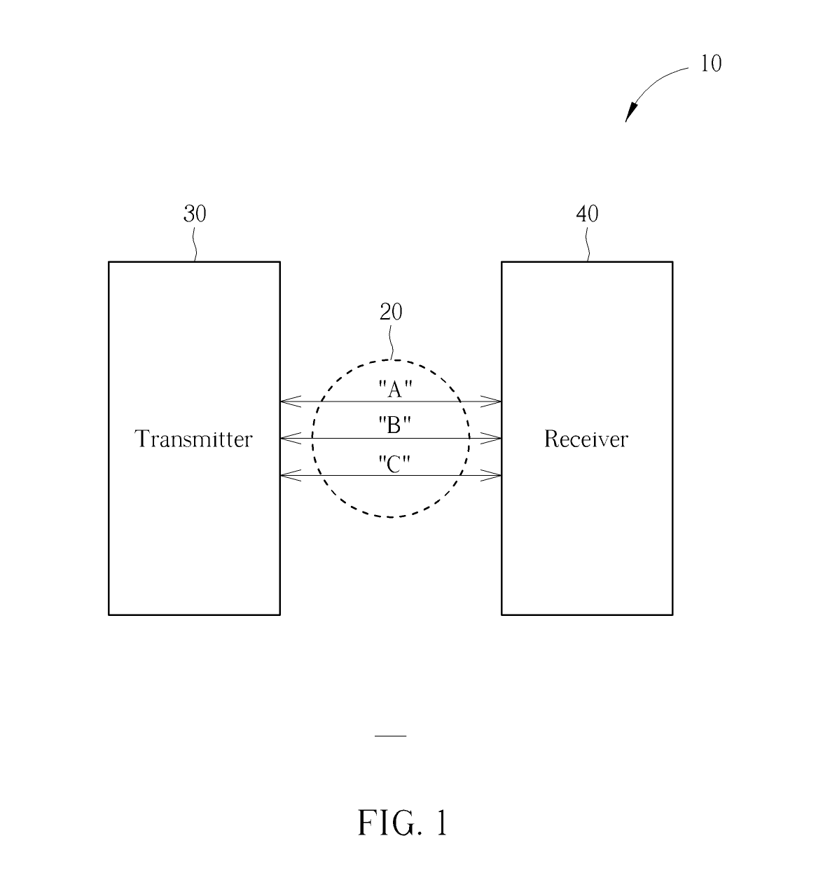

FIG. 1 illustrates an overview of a communication system according to one embodiment. The communication system 10 comprises a transmitter 30 and a receiver 40, where the transmitter 30 communicates with the receiver 40 through a multi-wire communication link 20. The multi-wire communication link may comprise three wires A, B, and C, and these three wires form a lane between the transmitter 30 and a receiver 40. The communication system 10 of the present invention is adaptable to a MIPI C-PHY configuration. For MIPI C-PHY configuration, signaling on the wires A, B and C comprises six wire states, which are called: +x, −x, +y, −y, +z, and 31 z.

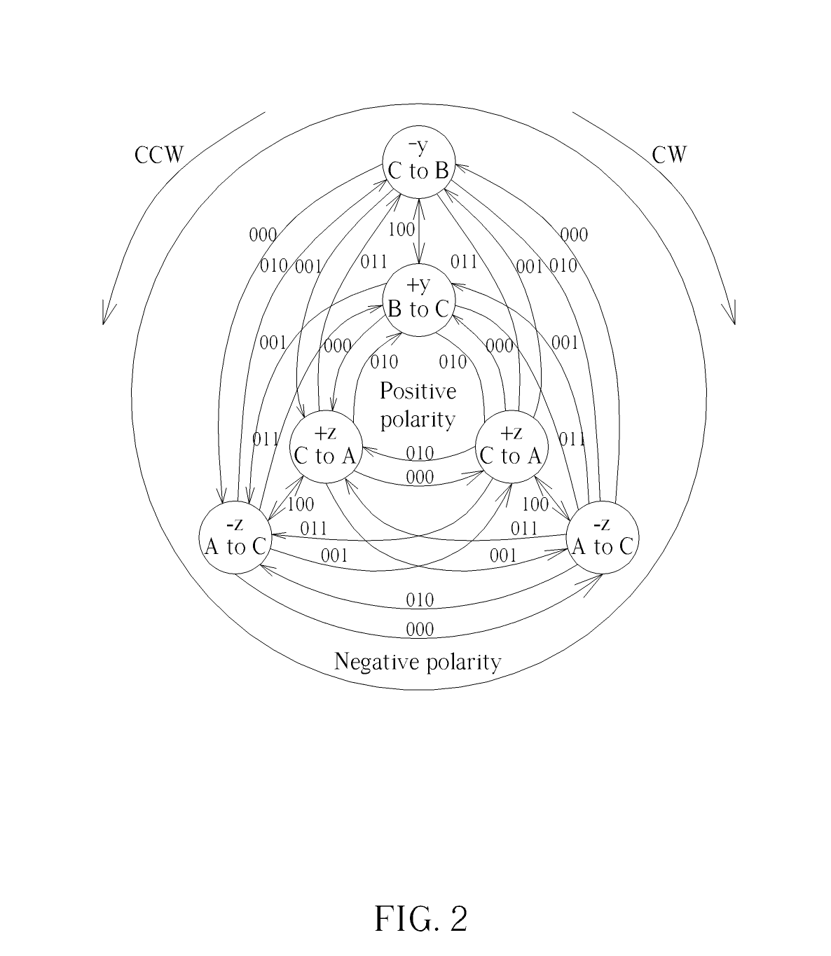

FIG. 2 illustrates a state diagram showing six wire states: +x, −x, +y, −y, +z, and −z and five possible transitions from a present wire state to a next wire state. A symbol value of the symbol transmitted through the multi-wire communication link 200 is correspondingly defined by the change in wire state values from one unit interval to the next. Typically, seven consecutive symbols are used to transmit 16 bits of information in the MIPI C-PHY configuration.

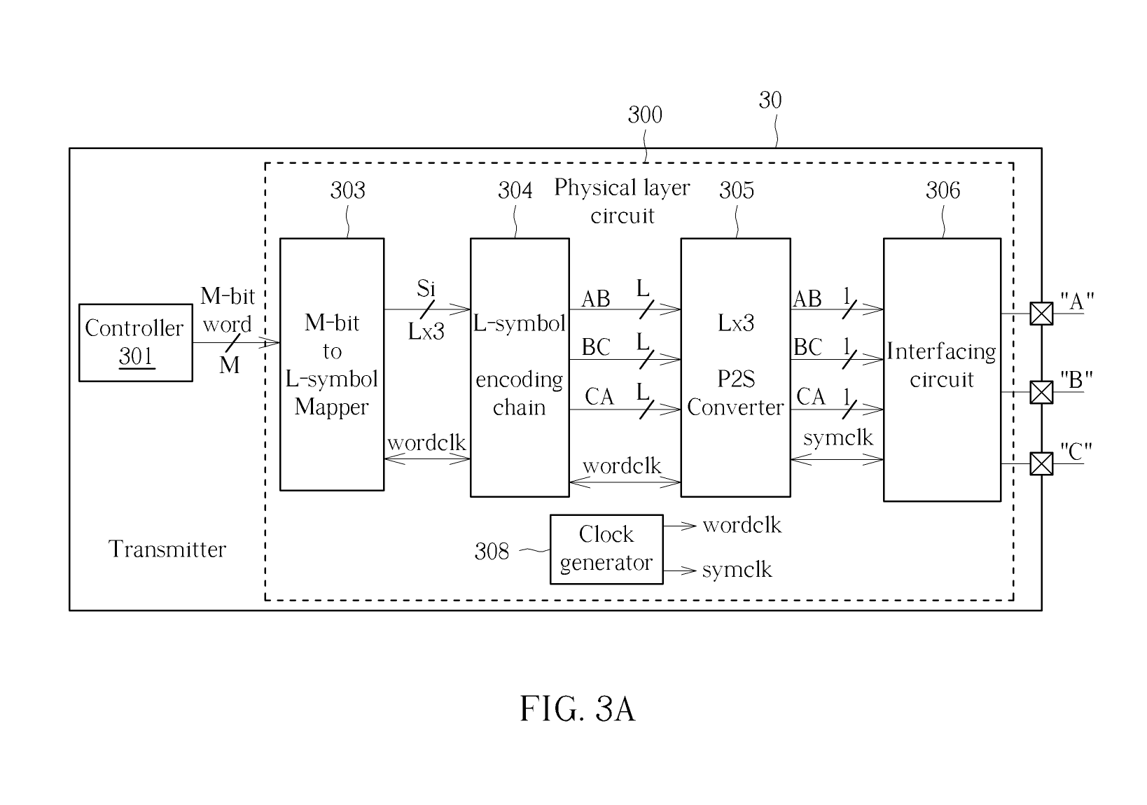

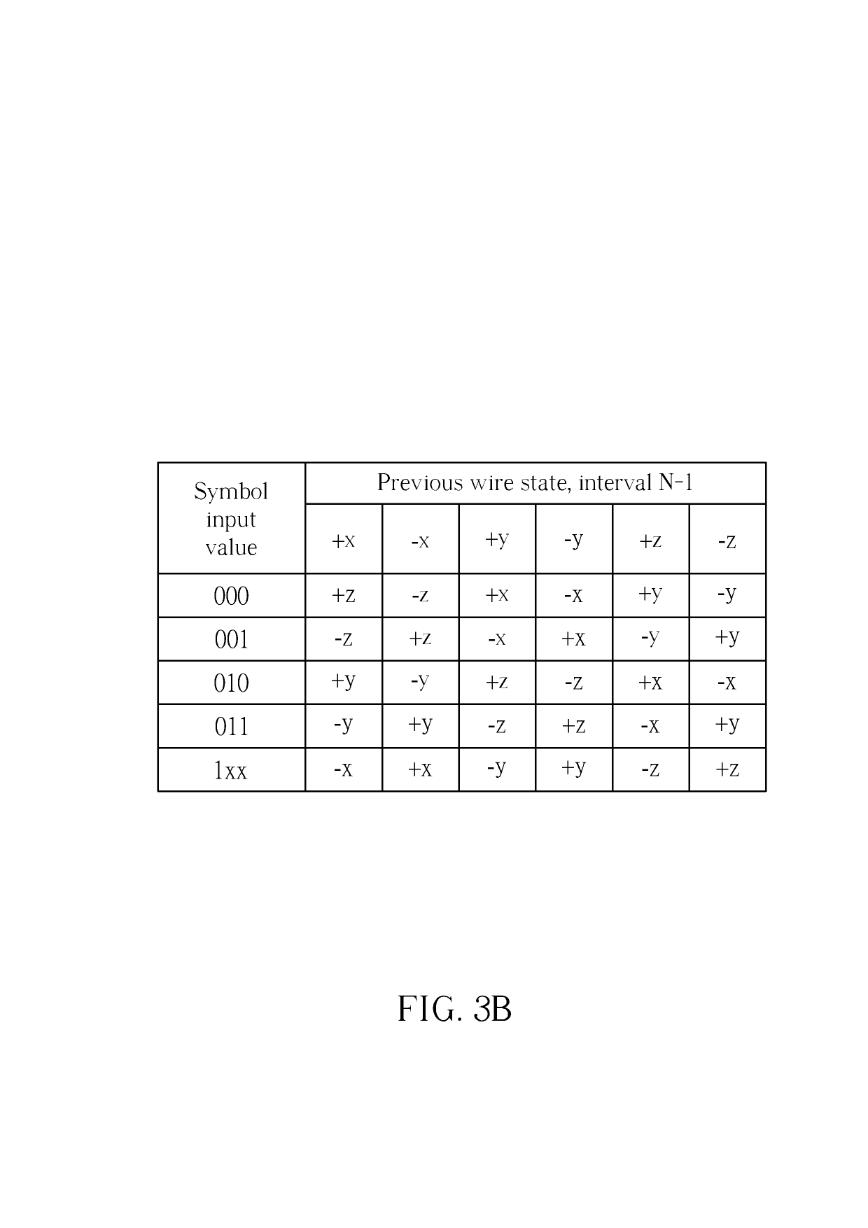

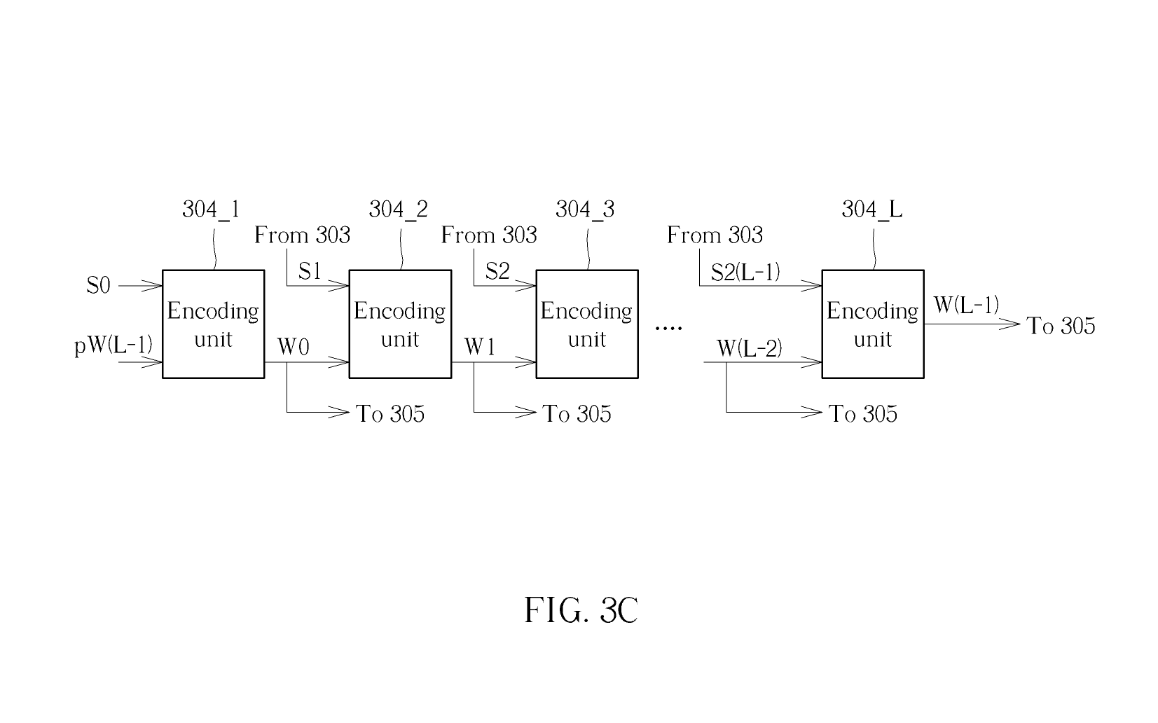

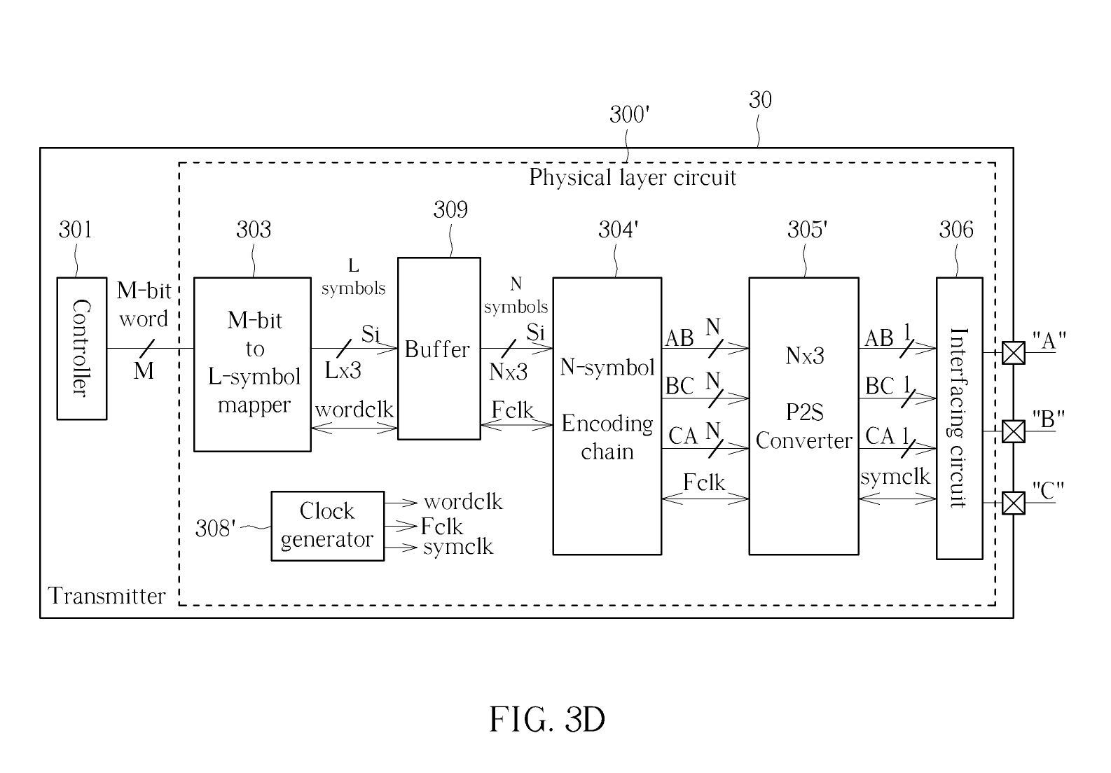

FIG. 3A illustrates a transmitter implemented based on an encoding architecture according to one embodiment of the present invention. The transmitter 30 comprises a controller 301 and a physical layer circuit 300. The controller 301 could be embodied by or otherwise included within a machine, such as a general purpose processor, a digital signal processor (DSP), an application specific integrated circuit (ASIC), a field programmable gate array (FPGA) or other programmable logic device or any combination thereof designed and programmed to perform or cause the performance of the functions described herein. The controller 301 is operable to provide a word of data. In a preferred embodiment, the controller 301 provides an M-bit word.

The physical layer circuit 300 comprises an M-bit to L-symbol mapper 303, an L-symbol encoding chain 304, an Lx3 parallel-to-serial (P2S) converter 305 and an interfacing circuit 306. The M-bit to L-symbol mapper 303 is operable to receive the M-bit word of data from the controller 301 and map the M-bit word of data to L symbols, where “M” could be an integer and any of multiples of 16, and “L” could be an integer and any of multiples of 7. For example, the mapper 303 is operable to receive a 16-bit word and map the received 16-bit word to 7 symbols according to a mapping function defined in MIDI C-PHY specification. Alternatively, the M-bit to L-symbol mapper 303 may map, a 32-bit word to 14 symbols, a 48-bit word to 21 symbols, a 64-bit word to 28 symbols, and so on.

Furthermore, in a preferred embodiment, each symbol comprises 3-bit symbol value. Each symbol is comprised of a flip, rotate and polarity bit, wherein each symbol value Si could be [Flip [i], Rotation [i], Polarity [i]].

The L-symbol encoding chain 304 is operable to encode the L symbols outputted by the M-bit to L-symbol mapper 303, which convert each symbol value Si to a wire state Wi (e.g. +x, −x, +y, −y, +z, and −z, as clearly defined in MIPI C-PHY specification). The wire state Wi is also comprised of 3-bit information [AB, BC, CA] to respectively indicate signaling state for wires A, B and C. The L-symbol encoding chain 304 encodes the symbol according to an encoding scheme illustrated by FIG. 3B, which is also defined in MIDI C-PHY specification.

FIG. 3C illustrates a detailed implementation of the L-symbol encoder chain 304 according to one embodiment of the present invention. As illustrated, the L-symbol encoding chain 304 comprises a plurality of encoding units 304_1-304_L. Each of the encoding units 304_1-304_L is operable to convert a symbol value Si of a symbol according to the symbol value Si and a wire state W (i-1) outputted by a previous one of the encoding units 304_1-304_L according to the encoding scheme illustrated by FIG. 3B.

For example, the encoding unit 304_2 is operable to encode according to a symbol value S1 of a second one of symbols outputted by the M-bit to L-symbol mapper 303 and a wire state W0 generated by the previous the encoding unit 304_1, the encoding unit 304_3 is operable to encode according to a symbol value S2 of a third one of symbols outputted by the M-bit to L-symbol mapper 303 and a wire state W1 generated by the previous encoding unit 304_2. Please note that, for the first encoding unit 304_1, it encodes according to a symbol value S0 of a first one of symbols outputted by the M-bit to L-symbol mapper 303 and a wire state pW (L-1), wherein the wire state pW (L-1) is outputted by the last one encoding unit 304_L during an encoding operation with respect to a word of data that is previously provided by the controller 301. In addition, the wire states W0-W (L-1) that are respectively generated by the encoding units 304 1-304 L, are further outputted to the Lx3 P2S converter 305.

In a preferred embodiment, a flip-flop (not shown) could be coupled between the M-bit to L-symbol mapper 303 and the L-symbol encoding chain 304, and another flip-flop (not shown) could be coupled between the L-symbol encoding chain 304 and the P2S converter 305 for performing timing alignment according to a word clock signal wordclk which correspond to a transmission duration of the word. In a preferred embodiment, the word clock signal wordclk could be a “High-Speed Transmit Word Clock “*TxWordClkHS”” as defined in MIDI C-PHY specification, which used to synchronize PPI signals in the high-speed transmit clock domain. However, this is not intended to be a limitation of the present invention.

Furthermore, circuitry of the physical layer circuit 300 could be divided into at least a physical coding sublayer (PCS) part and a physical medium attachment (PMA) part. In one embodiment, the encoding chain may be disposed in the PCS part while the P2S converter may be disposed in PMA part.

The Lx3 P2S converter 305 is operable to serialize the L wire states W0-W(L-1) generated by the L-symbol encoding chain 304 to output a sequence of 3-bit wire states WS according to the word clock signal wordclk. The interfacing circuit 306 is arranged to driving/controlling signal levels on the wires A, B, C according to the sequence of 3-bit wire states WS with a symbol clock signal symclk that corresponds to transmission duration of one symbol. In a preferred embodiment, the symbol clock signal symclk could be a “Lane High-Speed Transmit Symbol Clock “TxSymbolClkHS”” as defined in MIDI C-PHY specification, which provides the timing used to transmit high-speed symbol data over the lane interconnect.

The physical layer circuit 300 further comprises a clock generator 308 (which can be implemented with a phase lock loop (PLL)). The clock generator 308 is operable to generate the word clock signal wordclk and the symbol clock signal symclk, which correspond to transmission durations of one word and one symbol, respectively. In the case where the “M” is 16 and “L” is 7, the frequency of the word clock signal wordclk would be 1/7 of that of the symbol clock signal symclk since one word is mapped to 7 symbols. In the case where the “M” is 32 and “L” is 14, the frequency of the word clock signal wordclk would be 1/14 of that of the symbol clock signal symclk since one word is mapped to 14 symbols.

For data transmission between elements in the physical layer circuit 300, data buses of different widths are applied due to parallel to serial conversion. Between the controller 301 and the M-bit to L-symbol mapper 303, the data bus would be M bits wide. Between the M-bit to L-symbol mapper 303 and the L-symbol encoding chain 304, the data bus would Lx3 bits wide. Between the L-symbol encoding chain 304 and the Lx3 P2S converter 305, the data bus would Lx3 bits wide. Between the Lx3 P2S converter 305 and the interfacing circuit 306, the data bus would 3 bits wide.

According to various embodiments of the present invention, a N-symbol encoding chain may be utilized to encode more or fewer symbols than L symbols outputted by the M-bit to L-symbol mapper 303 during a cycle of encoding operation. In such embodiments, there would be some modifications made to the physical layer circuit 300 as mentioned above. Please refer to FIG. 3D for further details.

As shown by FIG. 3D, a physical layer circuit 300′ comprises an M-bit to L-symbol mapper 303, a first-in/first-out (FIFO) buffer 309, a N-symbol encoding chain 304′, a Nx3 P2S converter 305′ and an interfacing circuit 306. As mentioned above, the M-bit to L-symbol mapper 303 is operable to receive M-bit word of data from the controller 301 and map the M-bit word of data to L symbols as mentioned above. Since the N-symbol encoding chain 304′ is operable to encode more or fewer symbols than L symbols outputted by the M-bit to L-symbol mapper 303 during a cycle of encoding operation, a buffer is needed to solve asynchronous operations therebetween. Hence, the FIFO buffer 309 is utilized to store every L symbols outputted by the M-bit to L-symbol mapper 303 according to the word clock signal wordclk. During each cycle of encoding, the N-symbol encoding chain 304′ fetches N symbols from the FIFO buffer 309 according to a fractional clock signal Fclk, wherein the frequency of the fractional clock signal Fclk is 1/N of that of the symbol clock signal symclk.

Operations and principles of the N-symbol encoding chain 304′ is similar to the L-symbol encoding chain 304, which are both operable to encode the symbols outputted by the M-bit to L-symbol mapper 303 and convert each symbol value Si to a wire state Wi as what is defined in MIPI C-PHY specification. The difference between the N-symbol encoding chain 304′ and the L-symbol encoding chain 304 is the number of encoding units included therein. As shown by FIG. 3C, the L-symbol encoding chain 304 utilizes L encoding units 304_1-304_L to sequentially encode L symbols to L wire states. In contrast to this, the N-symbol encoding chain 304′ utilizes N encoding units 304_1-304_N to sequentially encode N symbols to N wire states. Similarly, there could be a flip-flop coupled between the FIFO buffer 309 and the N-symbol encoding chain 304′, and another flip-flop coupled between N-symbol encoding chain 304′ and the Nx3 P2S converter 305′ for performing timing alignment according to the fractional clock signal Fclk. However, this is not intended to be a limitation of the present invention.

The Nx3 P2S converter 305′ is operable to serialize the N wire states W0-W (N-1) generated by the N-symbol encoding chain 304′ to output a sequence of 3-bit wire states WS, wherein the Nx3 P2S converter 305′ serializes the N wire states W0-W (N-1) according to the fractional clock signal Fclk. The interfacing circuit 306 is arranged to driving/controlling signal levels on the wires A, B, C according to the sequence of wire states WS with the symbol clock signal symclk that corresponds to transmission duration of one symbol.

The physical layer circuit 300′ further comprises a clock generator 308′. The clock recovery device 308′ is operable to generate the word clock signal wordclk which corresponds to transmission duration of one word and the symbol clock signal symclk which correspond to transmission duration of one symbol. Additionally, the clock generator 308′ is also arranged to generate the fractional clock signal Fclk. In one embodiment, the clock recovery device 308′ could be implemented with a PLL. The frequency of the fractional clock signal Fclk would be 1/N of that of the symbol clock signal symclk, while the frequency of the word clock signal wordclk depends on “M” and “L”. In the case where the “M” is 16 and “L” is 7, the frequency of the word clock signal wordclk would be 1/7 of that of the symbol clock signal symclk. In the case where the “M” is 32 and “L” is 14, the frequency of the word clock signal wordclk would be 1/14 of that of the symbol clock signal symclk.

For data transmission between elements in the physical layer circuit 300′, data buses of different widths are applied due to parallel to serial conversion and the asynchronous operations. Between the controller 301 and the M-bit to L-symbol mapper 303, the data bus would be M bits wide. Between the M-bit to L-symbol mapper 303 and the buffer 309, the data bus would be Lx3 bits wide. Between the buffer 309 and the N-symbol encoding chain 304′, the data bus would be Nx3 bits wide. Between the N-symbol encoding chain 304′ and Nx3 P2S converter 305′, the data bus would be Nx3 bits wide. Between the Nx3 P2S converter 305′ and the interfacing circuit 306, the data bus would 3 bits wide.

Furthermore, operation of the physical layer circuit 300 and 300′ could be summarized into following step:
receiving a plurality of first symbols and converting a symbol value of each of the plurality of first symbols to a corresponding wire state, thereby to generate a plurality of wire states; and
receiving the plurality of wire states and serializing the plurality of wire states to provide a sequence of wire states.

Please note that the above-mentioned step of receiving a plurality of first symbols and converting a symbol value of each of them to a corresponding wire state may rely on a encoding chain having a plurality of encoding units, such as encoding chain 304 or 304′. Further details and/or sub-steps based on operations of the physical layer circuit 300 and 300′ are omitted here for sake of brevity.

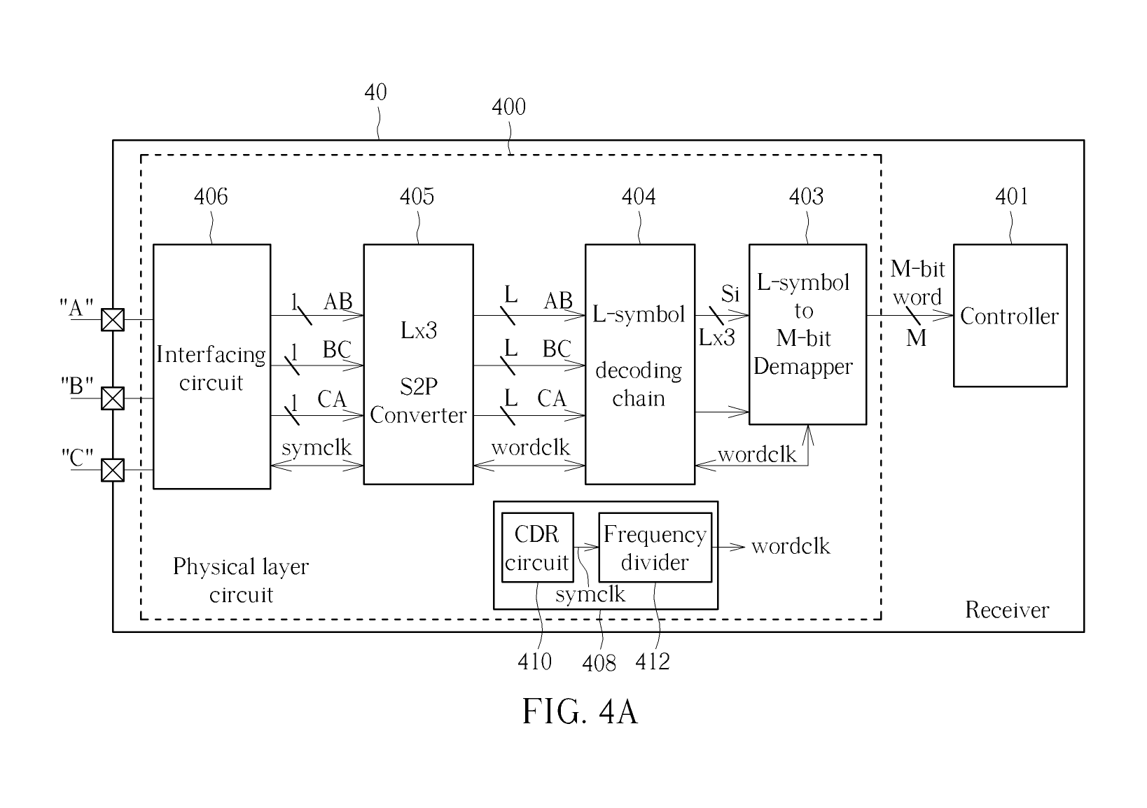

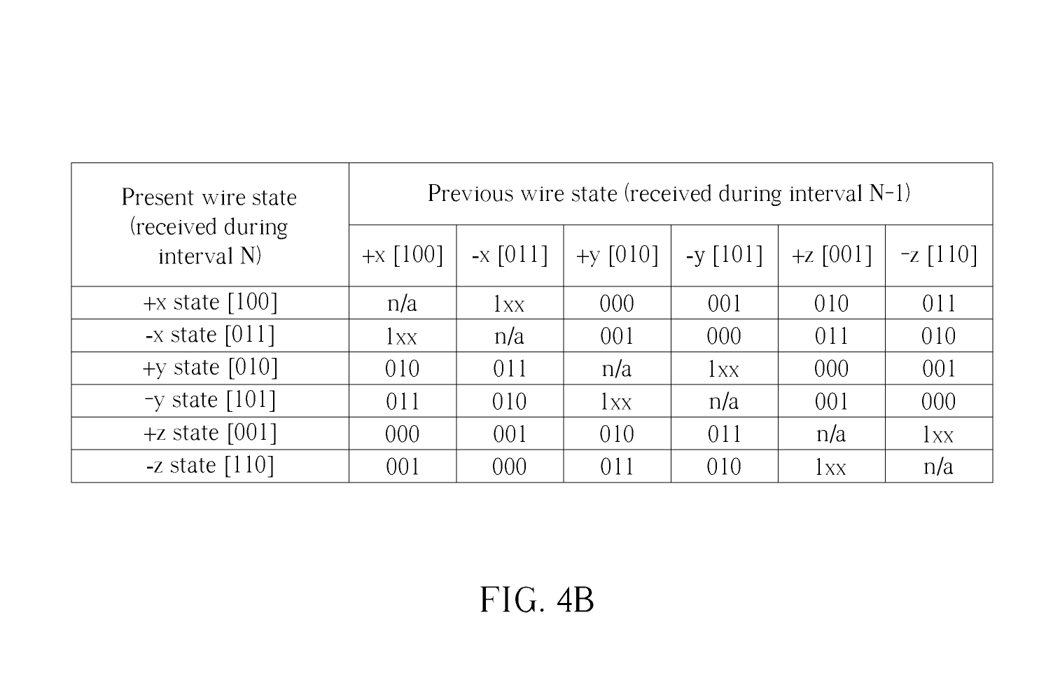

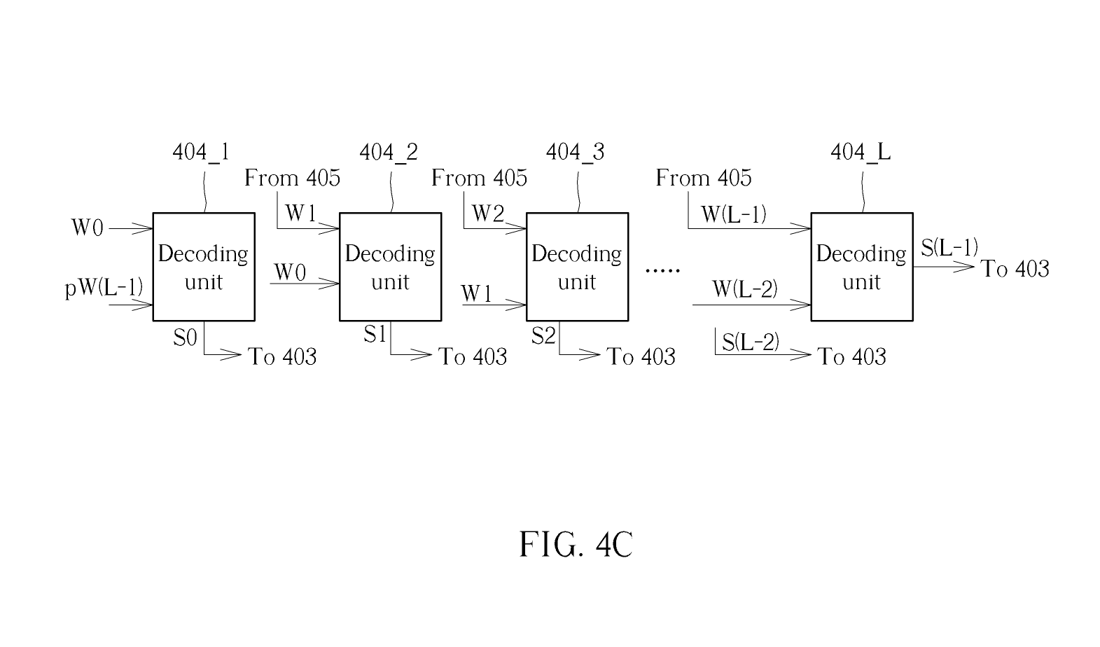

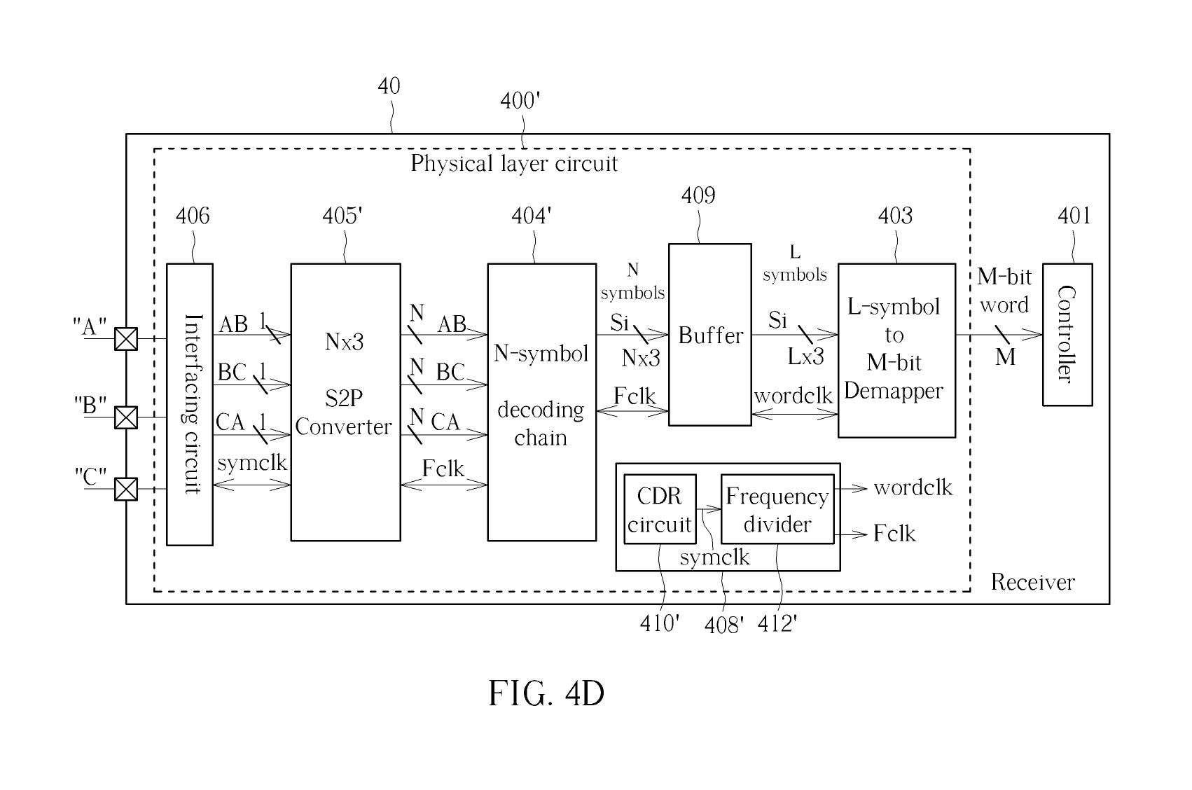

FIG. 4A illustrates a receiver implemented based on a decoding architecture according to one embodiment of the present invention. The receiver 40 of this embodiment could be used in communication with the transmitter 30 of the above-mentioned embodiment. The receiver 40 comprises a controller 401 and a physical layer circuit 400. The physical layer circuit 400 is operable to receive signals transmitted on the wires A, B, C, which corresponding to the data of word provided by the controller 301. Based on a series of operations performed by components in the physical layer circuit 400, a reproduced version of the data of word would be provided to the controller 401. The controller 401 is operable to process the word of data. The controller 401 could be embodied by or otherwise included within a machine, such as a general purpose processor, a digital signal processor (DSP), an application specific integrated circuit (ASIC), a field programmable gate array (FPGA) or other programmable logic device or any combination thereof designed and programmed to perform or cause the performance of the functions described herein.

The physical layer circuit 400 comprises an interfacing circuit 406, an Lx3 serial to parallel (S2P) converter 405, an L-symbol decoding chain 404, and an L-symbol to M-bit de-mapper 403. The interfacing circuit 406 is arranged to extract a sequence of 3-bit wire states WS from the wires, A, B and C according to a symbol clock signal symclk which corresponds to transmission duration of one symbol. In a preferred embodiment, the symbol clock signal symclk in the physical layer circuit 400 could be a “High-Speed Receive symbol Clock “RxSymbolClkHS””. However, this is not intended to be a limitation of the present invention.

The Lx3 S2P converter 405 is operable to deserialize the sequence of 3-bit wire states WS to output L wire states W0-W (L-1) according to the symbol clock signal symclk. The L-symbol decoding chain 404 is operable to decode the L wire states W0-W (L-1), which convert each wire state Wi to a symbol value Si. As mentioned above, the wire state Wi could be one of the six wire states: +x, −x, +y, −y, +z, and −z, as defined in MIPI C-PHY specification and represented by 3-bit information [AB, BC, CA. Each symbol is comprised of a flip, rotate and polarity bit and each symbol value Si could be represented by [Flip [i], Rotation [i], Polarity [i]]. The L-symbol decoding chain 404 decodes the wire state according to a decoding scheme illustrated by FIG. 4B, which is defined in MIPI C-PHY specification.

FIG. 4C illustrates a detailed implementation of the L-symbol decoder chain 404 according to one embodiment of the present invention. As illustrated, the L-symbol decoding chain 404 comprises L encoding units 404_1-404_L. Each of the decoding units 404_1-404_L is operable to convert a wire state Wi according to the symbol value wire state Wi and a symbol value S (i-1) outputted by a previous one of the decoding units 404_1-404_L according to the decoding scheme illustrated by FIG. 4B.

For example, the decoding unit 404_2 is operable to decode according to a second wire state W1 of the wire states outputted by the Lx3 S2P converter 405 and a symbol value S0 generated by the previous the decoding unit 404_1, the decoding unit 404_3 is operable to decode according to a third wire sate W2 of the wire states outputted by the Lx3 S2P converter 405 and a symbol value S1 generated by the previous the decoding unit 404_2. Please note that, for the first decoding unit 404 1, it decodes according to a first wire state W0 of the wire states outputted by the Lx3 S2P converter 405 and a symbol value pS (L-1), wherein the symbol value pS (L-1) is outputted by the last one decoding unit 404_N during an decoding operation with respect to a word of data that is previously received by the physical layer circuit 400. In addition, the symbol values S0-S (L-1) that are respectively generated by the decoding unit 404_1-404_L, are further outputted to the L-symbol to M-bit de-mapper 403.

In a preferred embodiment, a flip-flop (not shown) could be coupled between the Lx3 S2P converter 405 and the L-symbol decoding chain 404, and another flip-flop (not shown) could be coupled between the L-symbol decoding chain 404 and the L-symbol to M-bit 403 for performing timing alignment according to a word clock signal wordclk which correspond to transmission duration of one word. In a preferred embodiment, the symbol clock signal wordclk in the physical layer circuit 400 could be a “High-Speed Receive Word Clock “RxWordClkHS””. However, this is not intended to be a limitation of the present invention.

The L-symbol to M-bit de-mapper 403 is operable to receive the symbol values S0-S (L-1) of L symbols from the L-symbol decoding chain 404 and de-map the symbol values S0-S(L-1) of the L symbols to an M-bit word of data. For example, the L-symbol to M-bit de-mapper 403 is operable to receive symbol values S0-S6 of 7 symbols from the L-symbol decoding chain 404, and de-map the received symbol values S0-S6 of 7 symbols to a 16-bit word according to a de-mapping function defined in MIPI C-PHY specification. Alternatively, the L-symbol to M-bit mapper 403 may map, 14 symbols to a 32-bit word, 21 symbols to a 48-bit word, 28 symbols to a 64-bit word, and so on. After de-mapping, the word of data outputted by the L-symbol to M-bit mapper 403 will be sent to the controller 401

The physical layer circuit 400 further comprises a clock recovery device 408. The clock recovery device 408 is operable to generate the word clock signal wordclk which corresponds to transmission duration of one word and the symbol clock signal symclk which correspond to transmission duration of one symbol. In one embodiment, the clock recovery device 408 comprises a clock recovery circuit 410 and a frequency divider 412. The clock recovery circuit 410 is arranged to recover the symbol clock symclk signal embedded in signals received on wires A, B and C based on clock recovery techniques. The frequency divider 412 receives the symbol clock signal symclk and accordingly generates the word clock signal wordclk by performing frequency dividing operation on the symbol clock signal symclk. The frequency of the word clock signal wordclk depends on “M” and “L”. In the case where the “M” is 16 and “L” is 7, the frequency of the word clock signal wordclk would be 1/7 of that of the symbol clock signal symclk since 7 symbols are de-mapped to one word. In the case where the “M” is 32 and “L” is 14, the frequency of the word clock signal wordclk would be 1/14 of that of the symbol clock signal symclk since 14 symbols are de-mapped to one word.

For data transmission between elements in the physical layer circuit 400, data buses of different widths are applied due to serial to parallel conversion. Between the interfacing circuit 406 and the Lx3 S2P converter 405, the data bus would 3 bits wide. Between the Lx3 S2P converter 405 and the L-symbol decoding chain 404, the data bus would Lx3 bits wide. Between the L-symbol decoding chain 404 and the L-symbol to M-bit demapper 403, the data bus would Lx3 bits wide. Between the L-symbol to M-bit demapper 403 and the controller 401, the data bus would be M bits wide.

According to various embodiments of the present invention, during a cycle of decoding an N-symbol decoding chain may be utilized to decode to output more or fewer symbols than L symbols needed by L-symbol to M-bit de-mapper 403. In such embodiments, there would be some modifications made to the physical layer circuit 400 as mentioned above. Please refer to FIG. 4D for further details.

As shown by FIG. 4D, a physical layer circuit 400′ comprises an interfacing circuit 406, a Nx3 S2P converter 405′, a N-symbol decoding chain 404′, a FIFO buffer 409 and an L-symbol to M-bit de-mapper 403. The interfacing circuit 406 is arranged to extract a sequence of 3-bit wire states WS from the wires, A, B and C according to the symbol clock signal symclk. The Nx3 S2P converter 405 is operable to deserialize the sequence of 3-bit wire states WS to output N wire states W0-W (N-1) for the N-symbol decoding chain 404′ during a cycle of decoding. The Nx3 S2P converter 405′ deserialize the sequence of 3-bit wire states WS according to the symbol clock signal symclk.

Operations and principles of the N-symbol decoding chain 404′ is similar to the L-symbol decoding chain 404, which are both operable to decode the wire states outputted by S2P converter and convert each wire state Wi to a symbol value Si as what is defined in MIPI C-PHY specification. The difference between the N-symbol decoding chain 404′ and the L-symbol decoding chain 404 is the number of decoding units included therein. As shown by FIG. 4C, the L-symbol decoding chain 404 utilizes L decoding units 404_1-404_L to sequentially decode L wire states to L symbols. In contrast to this, the N-symbol decoding chain 404′ utilizes N decoding units 404_1-404_N to sequentially decode N wire states to N symbols.

Similarly, there could be a flip-flop coupled between the FIFO buffer 409 and the N-symbol decoding chain 404′, and another flip-flop coupled between N-symbol encoding chain 404′ and the Nx3 S2P converter 405′ for performing timing alignment according to a fractional clock signal Fclk, wherein the frequency of the fractional clock signal Fclk is 1/N of that of the symbol clock signal symclk. However, this is this is not intended to be a limitation of the present invention.

Since the N-symbol decoding chain 404′ is operable to output more or fewer symbols than L symbols needed by L-symbol to M-bit de-mapper 403 during a cycle of de-mapping, a buffer is also needed to solve the asynchronous operations there between. Hence, the FIFO buffer 409 is utilized to buffer every N symbols outputted by N-symbol decoding chain 404′ according to the fractional clock signal Fclk during a cycle of decoding. During a cycle of de-mapping, L-symbol to M-bit de-mapper 403 fetches L symbols from the FIFO buffer 409 according to the word clock signal wordclk.

The physical layer circuit 400′ further comprises a clock recovery device 408′. The clock recovery device 408′ is operable to generate the word clock signal wordclk which corresponds to transmission duration of one word and the symbol clock signal symclk which correspond to transmission duration of one symbol. Additionally, a clock recovery device 408′ is also arranged to generate the fractional clock signal Fclk. In one embodiment, the clock recovery device 408′ comprises a clock recovery circuit 410′ and a frequency divider 412′. The clock recovery circuit 410′ is arranged to recover the symbol clock symclk signal embedded in signals received on wires A, B and C based on clock recovery techniques. The frequency divider 412′ receives the symbol clock signal symclk and accordingly generates the word clock signal wordclk and the fractional clock signal Fclk by performing frequency dividing operation on the symbol clock signal symclk. The frequency of the fractional clock signal Fclk would be 1/N of that of the symbol clock signal symclk, while the frequency of the word clock signal wordclk depends on “M” and “L”. In the case where the “M” is 16 and “L” is 7, the frequency of the word clock signal wordclk would be 1/7 of that of the symbol clock signal symclk. In the case where the “M” is 32 and “L” is 14, the frequency of the word clock signal wordclk would be 1/14 of that of the symbol clock signal symclk.

For data transmission between elements in the physical layer circuit 400′, data buses of different widths are applied due to serial to parallel conversion and the asynchronous operations. Between the interfacing circuit 406 and the Nx3 S2P converter 405′, the data bus would 3 bits wide. Between the Nx3 S2P converter 405′ and the N-symbol decoding chain 404′, the data bus would be Nx3 bits wide. Between the N-symbol decoding chain 404′ and the buffer 409, the data bus would be Nx3 bits wide. Between the buffer 409 and the L-symbol to M-bit demapper 403, the data bus would be Lx3 bits wide. Between the L-symbol to M-bit demapper 403 and the controller 401, the data bus would be M bits wide.

Furthermore, operation of the physical layer circuit 400 and 400′ could be summarized into following step:
receiving a sequence of write states and deserializing the sequence of write states to provide a plurality of wire states; and
utilizing receiving the plurality of wire states and converting each of the plurality of wire states to a corresponding symbol value of a symbol, thereby to generate a plurality of first symbols.

Please note that the above-mentioned step of receiving the wire states and converting each of time to a corresponding symbol value may rely on a decoding chain having a plurality of decoding units, such as decoding chain 404 or 404′. Further details and/or sub-steps based on operations of the physical layer circuit 400 and 400′ are omitted here for sake of brevity.

A difference between encoding architecture of the conventional art and the present invention is the sequence of the P2S converter and the encoding circuit and the architecture of the encoding circuit. In encoding architecture of the conventional art, the P2S converter is prior to the encoding circuit, while in the present invention the encoding circuit (i.e., the encoding chain 304) is prior to the P2S converter. Another difference between encoding architecture of the conventional art and the present invention is the encoding circuit (i.e., the encoding chain 304) of the present invention is implemented by a plurality of encoding units coupled in series. Due to such differences, the encoding circuit (i.e., the encoding chain 304) of the present invention is allowed to complete encoding operations on multiple consecutive symbols (e.g. 7 symbols) within a word interval (i.e., the transmission duration of the multiple consecutive symbols), while the encoding circuit of the conventional art needs to complete an encoding operation on an individual symbol within a symbol interval (i.e., the transmission duration of a single symbol). This provides more margin in avoiding timing violation. That is, assuming that the bit rate of the communication system is 2.5 Gbps, the symbol clock must be run to 400 ps±50% duty cycle, which means an encoding operation of the conventional art needs to be completed within 200 ps in the worst case. That is, the gate delay of the encoding circuit of the conventional art cannot exceed 200 ps. In contrast to this, as there will be a complementation in clock skew between a present clock and a next clock, the encoding operations on N consecutive symbols of the present invention only needs to be completed within ((N-1)*400+200)ps. In other words, a single one of the encoding units in the present invention is allowed to complete an encoding operation within ((N-1)*400+200)/N ps, which will be much longer than 200 ps. Hence, requirement on the gate delay of an encoding unit is alleviated. Please note that the above explanations on the encoding architecture can be also applied to the decoding architecture. In view of above, the encoding and decoding architecture significantly alleviates the timing requirements on delays of the hardware components, thereby to avoid a potential timing violation in a high-speed serial data communication system.

Those skilled in the art will readily observe that numerous modifications and alterations of the device and method may be made while retaining the teachings of the invention. Accordingly, the above disclosure should be construed as limited only by the metes and bounds of the appended claims.

1. A physical layer circuit at a transmitter, comprising:
an encoding chain, having a plurality of encoding units coupled in series, arranged to receive a plurality of first symbols and convert a symbol value of each of the plurality of first symbols to a corresponding wire state, thereby to generate a plurality of wire states; and
a parallel-to-serial (P2S) converter, coupled to the encoding chain, arranged to receive the plurality of wire states and serialize the plurality of wire states to provide a sequence of wire states.

2. The physical layer circuit of claim 1, wherein at least one of the plurality of encoding units is arranged to convert the symbol value according to the symbol value and a previous wire state generated by a previous one of the encoding units in series, thereby to derive a present wire state.

3. The physical layer circuit of claim 1, further comprising:
a mapper coupled to the encoding chain, arranged to receive a word of data and map the word of data to generate at least the plurality of first symbols during a cycle of operation.

4. The physical layer circuit of claim 3, further comprising:
a buffer, couple to the mapper, arranged to buffer at least the plurality of first symbols generated by the mapper.

5. The physical layer circuit of claim 4, wherein the mapper is arranged to map the word of data to generate a plurality of second symbols during a cycle of operation, wherein the plurality of second symbols includes the plurality of first symbols or the plurality of first symbols includes the plurality of second symbols.

6. The physical layer circuit of claim 1, wherein the P2S converter is arranged to serialize the plurality of wire states to generate the sequence of wire states according to a clock signal that is associated with the word of data.

7. A method for use in a physical layer circuit at a transmitter, comprising:
receiving a plurality of first symbols and converting a symbol value of each of the plurality of first symbols to a corresponding wire state, thereby to generate a plurality of wire states; and
receiving the plurality of wire states and serializing the plurality of wire states to provide a sequence of wire states.

8. The method of claim 7, further comprising:
receiving a word of data and mapping the word of data to generate at least the plurality of first symbols during a cycle of operation.

9. The method of claim 8, further comprising:
buffering at least the plurality of first symbols.

10. The method of claim 9, the step of mapping the word of data comprises:
mapping the word of data to generate a plurality of second symbols during a cycle of operation, wherein the plurality of second symbols including the plurality of first symbols or the plurality of first symbols including the plurality of second symbols.

11. The method of claim 7, wherein step of serializing the plurality of wire states comprises:
serializing the plurality of wire states to generate the sequence of wire states according to a clock signal that is associated with the word of data.

12. A physical layer circuit at a receiver, comprising:
a serial-to-parallel (S2P) converter, arranged receive a sequence of write states transmitted through the multi-wire link and deserialize the sequence of write states to provide a plurality of wire states;
a decoding chain, having a plurality of decoding unit coupled in series, arranged to receive the plurality of wire states and convert each of the plurality of wire states to a corresponding symbol value of a symbol, thereby to generate a plurality of first symbols.

13. The physical layer circuit of claim 12, wherein at least one of the plurality of decoding units is arranged to convert the wire state according to the wire state that is received during interval (N) and a previous wire state that is received during interval (N-1).

14. The physical layer circuit of claim 12, further comprising:
a de-mapper coupled to the decoding chain, arranged to receive the plurality of first symbols and generate a word of data by de-mapping at least the plurality of first symbols during a cycle of operation.

15. The physical layer circuit of claim 14, further comprising:
a buffer coupled to the decoding chain, arranged to buffer the plurality of first symbols generated by the decoding chain.

16. The physical layer circuit of claim 15, wherein the de-mapper is arranged to generate the word of data by de-mapping a plurality of second symbols during a cycle of operation, wherein the plurality of second symbols includes the plurality of first symbols or the plurality of first symbols includes the plurality of second symbols.

17. The physical layer circuit of claim 12, wherein the S2P converter is arranged to deserialize the sequence of wire states to generate the plurality of wire states according to a clock signal that is associated with the symbol.

18. A method for use in a physical layer circuit at a receiver, comprising:
receiving a sequence of write states and deserializing the sequence of write states to provide a plurality of wire states; and
receiving the plurality of wire states and converting each of the plurality of wire states to a corresponding symbol value of a symbol, thereby to generate a plurality of first symbols.

19. The method of claim 18, further comprising:
receiving the plurality of first symbols and generating a word of data by de-mapping at least the plurality of first symbols during a cycle of operation.

20. The method of claim 19, further comprising:
buffering the plurality of first symbols.

21. The method of claim 20, wherein the step of generating the word of data comprises:
generating the word of data by de-mapping a plurality of second symbols during a cycle of operation, wherein the plurality of second symbols includes the plurality of first symbols or the plurality of first symbols includes the plurality of second symbols.

22. The method of claim 18, wherein the step of deserializing the sequence of wire states comprises:
deserializing the sequence of wire states to generate the plurality of wire states according to a clock signal that is associated with the symbol.

23. A communication system based on a multi-wire communication link, comprising:
a transmitter, comprising:
a controller arranged to provide a word of data;
a first physical layer circuit, coupled to the controller, arranged to generate a sequence of wire states according to the word of data comprising:
an encoding chain arranged to convert a plurality of symbols that are not serialized into a plurality of wire states;
a first interfacing circuit coupled to the first physical layer circuit and the multi-wire communication link, arranged to controlling levels of a plurality of wires of the multi-wire communication link according to a sequence of wire states generated by the first physical layer circuit;
a receiver, comprising:
a second interfacing circuit, coupled to the multi-wire communication link, arranged extract the sequence of wire states from the plurality of wires of the multi-wire communication link;
a second physical layer unit coupled to the second interfacing circuit, arranged to reproduce the word of data according the sequence of wire states, comprising:
a decoding chain arranged to convert a plurality of wire states, which are deserialized from the sequence of the wire states, into a plurality of symbols;
a controller, coupled to the second physical layer circuit, arranged to receive and process the word of data.
